(19) United States
(12) Patent Application Publication
(10) Pub. No.: US 2021/0059048 A1
(43) Pub. Date: Feb. 25, 2021

(54) Copper-Clad Laminate, Printed Circuit Board and Method for Manufacturing Printed Circuit Board

(71) Applicant: AAC Technologies Pte. Ltd., Singapore City (SG)

(72) Inventors: Hongyuan Wang, Shenzhen (CN); Hezhi Wang, Shenzhen (CN)

(21) Appl. No.: 16/992,092

(22) Filed: Aug. 12, 2020

(30) Foreign Application Priority Data
Aug. 21, 2019 (CN) 201910772925.0

(51) Int. Cl. H05K 1/03; H05K 3/02; B32B 5/02; B32B 15/14; B32B 15/20; B32B 5/26

(52) U.S. Cl. CPC H05K 1/0366; B32B 2307/546; B32B 5/022; B32B 15/14; B32B 15/20; B32B 5/26; H05K 1/0373; B32B 2262/101; B32B 2260/021; B32B 2260/046; B32B 2270/00; B32B 2457/08; B32B 2264/1021; B32B 2264/1022; B32B 2250/40; B32B 2307/206; H05K 3/022

(57) ABSTRACT

A copper-clad laminate includes an insulating substrate and a copper foil layer covering a surface of the insulating substrate. The insulating substrate includes at least one first insulating layer, and the first insulating layer is a blend of a surface fiber felt made of fibers and resin or a blend of a non-woven fabric-reinforced composite material and resin, and the copper foil layer is attached to an outer surface of the first insulating layer. The present disclosure also provides a printed circuit board, which is made from the copper-clad laminate of the present disclosure. The present disclosure also provides a method for manufacturing the printed circuit board. Compared with the related arts, the copper-clad laminate and the printed circuit board of the present disclosure have improved dielectric properties.

### CROSS REFERENCE TO RELATED APPLICATIONS

This non-provisional patent application is a Continuation application of International Application PCT/CN2019/104827, filed on Sep. 9, 2019, which claims priority from Patent Application No. 201910772925.0 filed in The People's Republic of China on Aug. 21, 2019. These two applications are incorporated herein by reference.

### TECHNICAL FIELD

The present disclosure relates to the technical field of copper-clad laminates, and in particular to a copper-clad laminate and a printed circuit board.

### BACKGROUND

In recent years, with the development of electronic information technology, miniaturization and high density installation of electronic devices, and large capacity and high speed transmission of information have been putting forward increasingly higher requirements on the comprehensive performance of printed circuit boards, including heat resistance, water-absorption, chemical resistance, mechanical properties, dimensional stability, dielectric properties, and etc.

In related arts, a printed circuit board includes a copper-clad laminate, and the copper-clad laminate includes a resin substrate and a copper foil attached onto the resin substrate. The resin substrate is made by mixing resin and fiber materials.

However, due to the difference in fiber content in the fiber material at intersecting points and non-intersecting points of the transverse and longitudinal fibers, the fibers in the resin substrate are unevenly distributed, which may result in a large difference in dielectric properties at different locations, affecting the dielectric uniformity of the material, and hence restricting its application to a certain extent.

Therefore, it is necessary to provide a new copper-clad laminate and a printed circuit board to solve the above technical problems.

### SUMMARY

Embodiments of the present disclosure are directed to a copper-clad laminate and a printed circuit board with improved dielectric properties.

In one independent aspect, a copper-clad laminate generally includes an insulating substrate and copper foil layer covering a surface of the insulating substrate. The insulating substrate includes at least one first insulating layer, the first insulating layer being one of a blend of surface fiber felt made of fibers and resin, and a blend of a non-woven fabric-reinforced composite material and resin. The copper foil layer is attached to an outer surface of the first insulating layer.

In one embodiment, a fiber volume of the first insulating layer accounts for 20%-85% of the total volume of the first insulating layer.

In one embodiment, the fiber is one of a glass fiber, a quartz fiber and an organic fiber.

In one embodiment, the at least one first insulating layer comprises two layers which are spaced from each other, the insulating substrate further comprises a second insulating layer sandwiched between the two first insulating layers, the copper foil layer is attached to a side of the first insulating layer away from the second insulating layer, and the second insulating layer is made of a fiber-reinforced composite material.

In one embodiment, a volume fraction of the fiber volume of the second insulating layer to the total volume of the second insulation layer is equal to a volume fraction of the fiber volume of the first insulating layer to the total volume of the first insulation layer, and the fiber volume of the first insulating layer accounts for 20%-85% of the total volume of the first insulating layer.

In one embodiment, the resin is a blend of a resin matrix and a filler, the resin matrix comprises one or more of polyphenylene ether, cyanate ester, epoxy resin, benzoxazine, hydrocarbon resin, bismaleimide and polytetramethylene, and the filler comprises at least one of organic microspheres, silica and titania.

In one embodiment, a particle size of the filler is 0.1 μm to 5 μm.

In another independent aspect, a printed circuit board is provided which includes a copper-clad laminate as described above.

In still another independent aspect, a method for manufacturing the printed circuit board described above is provided. The method includes impregnating a surface fiber felt or a non-woven fabric with resin, and drying the impregnated surface surface fiber felt or impregnated non-woven fabric to obtain a first insulating layer prepreg; laying the copper foil layer on the first insulating layer prepreg, and then performing a predetermined thermosetting process on the copper foil layer and the first insulating layer prepreg that are laid up to obtain a copper-clad laminate; and performing exposing, developing, etching and surface treatment processes on the copper-clad laminate according to a designed circuit to obtain the printed circuit board.

Compared with copper-clad laminate in the related arts, the copper-clad laminate of the present disclosure includes an insulating substrate and a copper foil layer covering a surface of the insulating substrate, the insulating substrate includes at least one first insulating layer, the first insulating layer is a blend of a surface fiber felt made of fibers and resin or a blend of a non-woven fabric-reinforced composite material and resin, and the copper foil layer is attached to an outer surface of the first insulating layer. In the above structure, fibers can be evenly distributed in the first insulating layer, which can effectively improve the dielectric properties of the insulating substrate, and hence improve the dielectric properties of the copper-clad laminate. The printed circuit board of the present disclosure adopts the above copper-clad laminate, which can also have effectively optimized dielectric properties.

Independent features and/or independent advantages of this disclosure may become apparent to those skilled in the art upon review of the detailed description, claims and drawings.

### BRIEF DESCRIPTION OF THE DRAWINGS

FIG. 1 is a schematic view of a copper-clad laminate according to a first embodiment of the present disclosure;

FIG. 2 is a schematic view of fiber distribution of a first insulating layer of the copper-clad laminate of the present disclosure;

FIG. 3 is a flow chart of a method for manufacturing a printed circuit board according to the first embodiment of the present disclosure;

FIG. 4 is a schematic view of a copper-clad laminate according to a second embodiment of the present disclosure; and

FIG. 5 is a schematic view of a printed circuit board according to one embodiment of the present disclosure.

### DESCRIPTION OF THE EMBODIMENTS

The present disclosure will be described further below with reference to the accompanying drawings and embodiments.

### First Embodiment

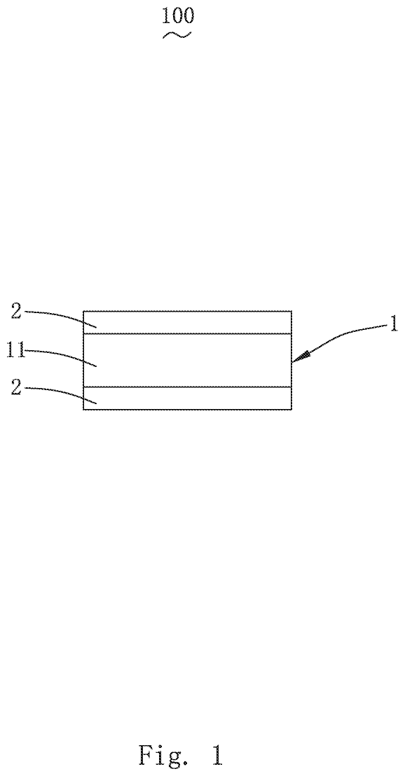

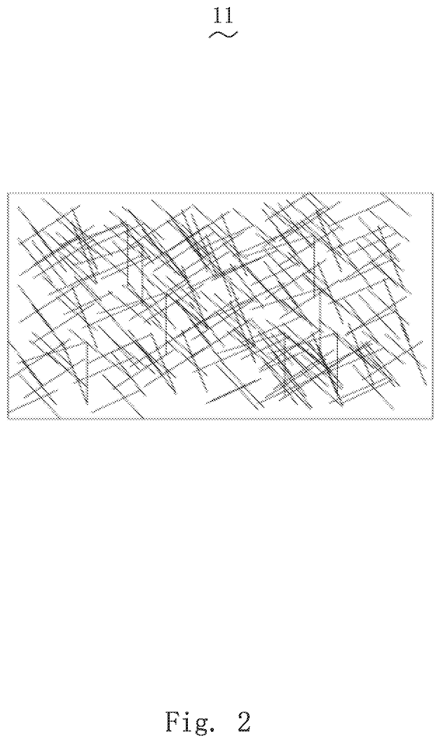

Please referring to FIGS. 1-2, the first embodiment of the present disclosure provides a copper-clad laminate 100, which includes an insulating substrate 1 and at least one copper foil layer 2.

The insulating substrate 1 includes a first insulating layer 11. The first insulating layer 11 is a blend of a surface fiber felt made of fibers and resin or a blend of a non-woven fabric-reinforced composite material and resin.

More specifically, the resin is a blend of a resin matrix and a filler.

The fiber is one of a glass fiber, a quartz fiber and an organic fiber, which can be selected according to actual requirements.

If a fiber volume fraction of the first insulating layer 11 is too low, the prepared composite material can be poor in mechanical properties, and low in dielectric constant and water absorption; if the fiber volume fraction of the first insulating layer 11 is too high, it can easily cause the surface of the material to become uneven due to lack of resin, resulting in defects such as, wrinkles, fiber lines, on the surface after cladding copper. Therefore, in order to ensure the mechanical properties, dielectric properties and water absorption of the first insulating layer 11, the fiber volume of the first insulating layer preferably accounts for 20%-85% of the total volume of the first insulating layer.

For the first insulating layer 11 of the first embodiment, a relationship between the fiber volume and the performance thereof is shown in table 1.

TABLE 1
Comprehensive performance of the first insulation layer
With different fiber volume fractions

| | | | | |
|---|---|---|---|---|
| Fiber volume | 20% | 30% | 50% | 85% |
| fraction | | | | |
| Dielectric | 3.28 | 3.62 | 4.31 | 5.62 |
| constant (1 GHz) | | | | |
| Bending strength | 221 Mpa | 293 Mpa | 437 Mpa | 690 Mpa |
| Water absorption | 0.06% | 0.08% | 0.14% | 0.23% |
| (23° C./24 h) | | | | |

When the fiber volume of the first insulating layer 11 accounts for 20% of the total volume of the first insulating layer 11, the dielectric constant of the first insulating layer 11 at a frequency of 1 GHz is 3.28, the bending strength is 221 Mpa, and the water absorption at ambient temperature is 0.06%.

When the fiber volume of the first insulating layer 11 accounts for 30% of the total volume of the first insulating layer 11, the dielectric constant of the first insulating layer 11 at a frequency of 1 GHz is 3.62, the bending strength is 293 Mpa, and the water absorption at ambient temperature is 0.08%.

When the fiber volume of the first insulating layer 11 accounts for 50% of the total volume of the first insulating layer 11, the dielectric constant of the first insulating layer 11 at a frequency of 1 GHz is 4.31, the bending strength is 437 Mpa, and the water absorption at ambient temperature is 0.14%.

When the fiber volume of the first insulating layer 11 accounts for 85% of the total volume of the first insulating layer 11, the dielectric constant of the first insulating layer 11 at a frequency of 1 GHz is 5.62, the bending strength is 690 Mpa, and the water absorption at ambient temperature is 0.23%.

The resin matrix includes one or more of polyphenylene ether, cyanate ester, epoxy resin, benzoxazine, hydrocarbon resin, bismaleimide, and polytetramethylene. In this embodiment, the resin matrix is polyphenylene ether. Of course, the resin matrix can also be specifically selected according to actual requirements.

The filler includes at least one of organic microspheres, silica and titania. The silica and the titania are used as inorganic fillers, and the addition of the inorganic filler can effectively adjust the dielectric constant of the resin, enhance the thermal properties thereof, and improve the flame resistance of the substrate to a certain extent. The organic microspheres are used as organic fillers, which can increase the interface strength of the filler and the resin matrix, making distribution of the filler in the resin more even, thereby avoiding the problem of filler sedimentation, and ensuring the stability of the material properties of the resin. The filler is in the form of particles, and a particle size of the particles directly affects the stability after mixing with the resin matrix. The mixing stability of the filler and the resin matrix can be effectively improved by reducing the particle size of the filler. Here, as a preferred embodiment, the particle size of the filler is 0.1 μm to 5 μm.

The copper foil layer 2 covers a surface of the insulating substrate 1. More specifically, the copper foil layer 2 is attached to an outer surface of the first insulating layer 11.

In this embodiment, the copper foil layer 2 is one of a rolled copper and an electrolytic copper. Further, a thickness of the copper foil layer 2 is 8 μm to 50 μm.

Furthermore, a contact surface between the copper foil layer 2 and the first insulating layer 11 has a roughness Rz of 1.2 μm to 6 μm, which effectively increases the smoothness of the contact surface, making a bonding between the copper foil layer 2 and the first insulating layers 11 more reliable, avoiding obvious fiber lines on the surface of the copper-clad laminate 100, and improving the reliability of the copper-clad laminate 100 as a whole.

As a preferred embodiment, the first insulating layer 11 is a blend of surface fiber felt and resin. A schematic view of the fiber distribution in the first insulating layer 11 is shown in FIG. 2. Since the surface fiber felt is a structure made of randomly distributed multi-layer fibers, there is no obvious void in the structure, such that the fibers are distributed evenly in the surface fiber felt. This can improve the uniformity of the dielectric properties at the woven and non-woven points, effectively improve the dielectric properties of the insulating substrate 1, thus resulting in an improved dielectric properties of the copper-clad laminate 100. Moreover, due to the even distribution of the fibers of the surface fiber felt, the problems of large difference between the transverse and longitudinal mechanical properties and low mechanical strength in a direction perpendicular to the fibers are avoided, and the mechanical properties of the substrate 1 are effectively improved to thereby improve the mechanical properties of the copper-clad laminate 100.

At the same time, the surface fiber felt is a sheet-like product made of continuous strands or chopped strands which are non-directionally bound together by a chemical binder or mechanical action, which can be produced just by chopped fibers without weaving, which simplifies the manufacturing process and reduces the cost. Therefore, the manufacturing cost of the insulating substrate 1 and hence the cost of the copper-clad laminate 100 can be reduced. In addition, a surface density of the surface fiber felt can be controlled below 10 g/m2 according to actual needs, so that the resin can better impregnate the surface fiber felt, thus reducing the difficulty of manufacturing the insulating substrate 1, and hence making it possible for making an ultra-thin composite substrate.

Of course, the structural form of the first insulating layer 11 is not limited to the above, and it also can be a blend of non-woven fabric reinforced composite material and resin. In the non-woven fabric reinforced composite material, textile staple fibers or filaments are arranged directionally or randomly to form a web structure with the internal fibers being evenly distributed, which can also effectively improve the dielectric properties of the insulating substrate 1, thereby improving the dielectric properties of the copper-clad laminate 100.

It is noted that the insulating substrate shall not be limited to any particular structural form. The insulating substrate may be a single-layer structure consisting of one such first insulating layer, or may alternatively be a multi-layer structure consisting of multiple such first insulating layers laminated each other.

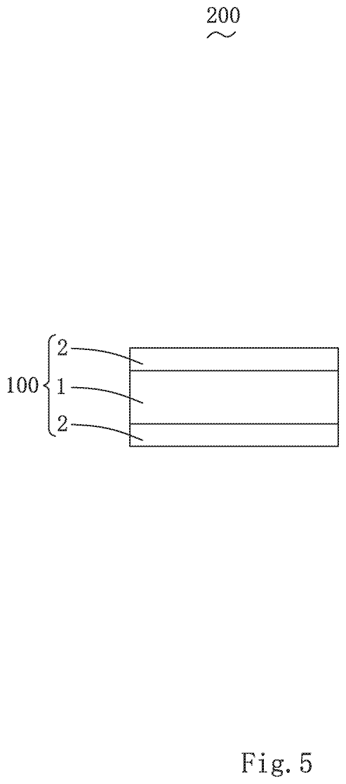

As shown in FIG. 5, the present disclosure also provides a printed circuit board 200, which includes the copper-clad laminate disclosed herein.

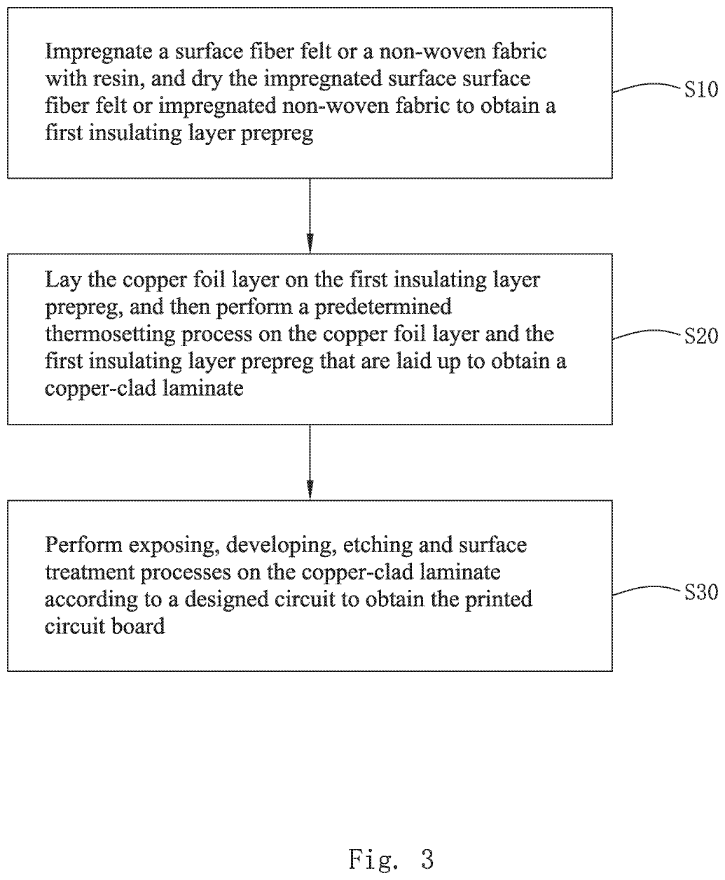

Referring to FIG. 3, a method for manufacturing the printed circuit board 200 includes the following steps.

At step S10, a surface fiber felt or non-woven fabric is impregnated with resin, and the surface fiber felt or non-woven fabric impregnated with the resin is dried to obtain a first insulating layer prepreg;

At step S20, a copper foil layer is laid on the first insulating layer prepreg, and then a predetermined thermosetting process is performed on the copper foil layer and the first insulating layer prepreg that are laid up to obtain a copper-clad laminate; and

At step S30, the copper-clad laminate undergoes exposing, developing, etching and surface treatment processes according to a designed circuit to obtain the printed circuit board.

Since the copper-clad laminate has improved dielectric properties and mechanical properties, the printed circuit board 200 manufactured from the copper-clad laminate also has improved dielectric properties and mechanical properties.

### Second Embodiment

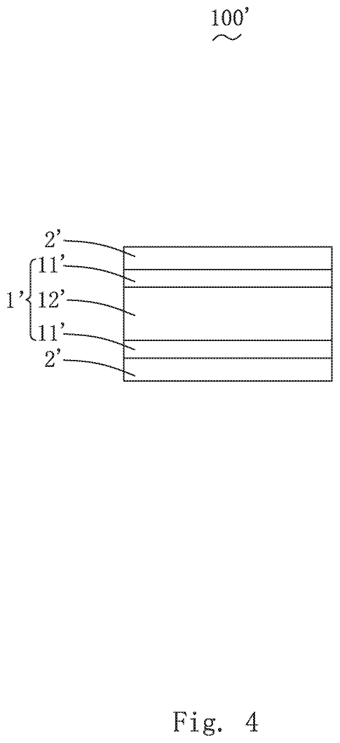

Referring to FIG. 4, in order to meet the requirements of products for different thicknesses in actual applications, a second insulating layer may be added to the insulating substrate. For example, a copper-clad laminate 100′ of a second embodiment includes an insulating substrate 1′ and at least one copper foil layer 2′.

The insulating substrate 1′ includes a plurality of first insulating layers 11′ and a second insulating layer 12′. The insulating substrate 1′ is a multi-layer composite structure consisting of the first insulating layers 11′ and the second insulating layer 12′.

Specifically, the first insulating layers 11′ include two layers, and the two layers are spaced from each other. The second insulating layer 12′ is sandwiched between the two first insulating layers 11′. The copper foil layer 2′ is attached to a side of the first insulating layer 11′ away from the second insulating layer 12′.

The structure and performance of the first insulating layer 11′ of the second embodiment are the same as those of the first insulating layer 11 of the first embodiment, which are therefore not repeated herein. The structure and performance of the second insulating layer 12′ of the second embodiment are mainly described below.

The second insulating layer 12′ is made of a fiber-reinforced composite material. The fiber-reinforced material includes at least one of a fiber fabric reinforced material made of fibers and a non-woven fabric reinforced material, which can be specifically selected according to actual requirements.

More preferably, a volume fraction of the fiber volume of the second insulating layer 12′ to the total volume of the second insulation layer 12′ is equal to a volume fraction of the fiber volume of the first insulating layer 11′ to the total volume of the first insulation layer 11′, in which, the fiber volume of the first insulating layer 11′ accounts for 20%-85% of the total volume of the first insulating layer 11′, and the fiber volume of the second insulating layer 12′ also accounts for 20%-85% of the total volume of the second insulating layer 12′.

It should be noted that the second insulating layer 12′ is mainly used to adjust a thickness of the copper-clad laminate 100′ so that the copper-clad laminate 100′ meets the thickness requirements of different application scenarios, and the specific thickness of the second insulating layer 12′ may be specifically designed according to different application scenarios.

Compared with the copper-clad laminates in the related arts, the copper-clad laminate of the present disclosure includes an insulating substrate and a copper foil layer covering a surface of the insulating substrate, the insulating substrate includes at least one first insulating layer, the first insulating layer is a blend of a surface fiber felt made of fibers and resin or a blend of non-woven fabric-reinforced composite material and resin, and the copper foil layer is attached to an outer surface of the first insulating layer. In the above structure, fibers can be evenly distributed in the first insulating layer, which can effectively improve the dielectric properties of the insulating substrate, and hence improve the dielectric properties of the copper-clad laminate The printed circuit board of the present disclosure adopts the above copper-clad laminate, which can also have effectively optimized dielectric properties.

Although the disclosure is described with reference to one or more embodiments, it will be apparent to those skilled in the art that various modifications and variations can be made to the disclosed structure and method without departing from the scope or spirit of the disclosure. In view of the foregoing, it is intended that the present disclosure cover modifications and variations of this invention provided they fall within the scope of the following claims and their equivalents.

What is claimed is:

1. A copper-clad laminate comprising:
an insulating substrate comprising at least one first insulating layer, the first insulating layer being one of a blend of surface fiber felt made of fibers and resin, and a blend of a non-woven fabric-reinforced composite material and resin; and
a copper foil layer covering and attached to an outer surface of the first insulating layer.

2. The copper-clad laminate of claim 1, wherein a fiber volume of the first insulating layer accounts for 20%-85% of the total volume of the first insulating layer.

3. The copper-clad laminate of claim 2, wherein the fiber is one of a glass fiber, a quartz fiber and an organic fiber.

4. The copper-clad laminate of claim 1, wherein the at least one first insulating layer comprises two layers which are spaced from each other, the insulating substrate further comprises a second insulating layer sandwiched between the two first insulating layers, the copper foil layer is attached to a side of the first insulating layer away from the second insulating layer, and the second insulating layer is made of a fiber-reinforced composite material.

5. The copper-clad laminate of claim 4, wherein a volume fraction of the fiber volume of the second insulating layer to the total volume of the second insulation layer is equal to a volume fraction of the fiber volume of the first insulating layer to the total volume of the first insulation layer, and the fiber volume of the first insulating layer accounts for 20%-85% of the total volume of the first insulating layer.

6. The copper-clad laminate of claim 1, wherein the resin is a blend of a resin matrix and a filler, the resin matrix comprises one or more of polyphenylene ether, cyanate ester, epoxy resin, benzoxazine, hydrocarbon resin, bismaleimide and polytetramethylene, and the filler comprises at least one of organic microspheres, silica and titania.

7. The copper-clad laminate of claim 6, wherein a particle size of the filler is 0.1 μm to 5 μm.

8. A printed circuit board comprising a copper-clad laminate, the copper-clad laminate comprising:
an insulating substrate comprising at least one first insulating layer, the first insulating layer being one of a blend of a surface fiber felt made of fibers and resin, and a blend of a non-woven fabric-reinforced composite material and resin; and
a copper foil layer covering and attached to an outer surface of the first insulating layer.

9. The printed circuit board of claim 8, wherein a fiber volume of the first insulating layer accounts for 20%-85% of the total volume of the first insulating layer.

10. The copper-clad laminate of claim 9, wherein the fiber is one of a glass fiber, a quartz fiber and an organic fiber.

11. The printed circuit board of claim 8, wherein the at least one first insulating layer comprises two layers which are spaced from each other, the insulating substrate further comprises a second insulating layer sandwiched between the two first insulating layers, the copper foil layer is attached to a side of the first insulating layer away from the second insulating layer, and the second insulating layer is made of a fiber-reinforced composite material.

12. The printed circuit board of claim 11, wherein a volume fraction of the fiber volume of the second insulating layer to the total volume of the second insulation layer is equal to a volume fraction of the fiber volume of the first insulating layer to the total volume of the first insulation layer, and the fiber volume of the first insulating layer accounts for 20%-85% of the total volume of the first insulating layer.

13. The printed circuit board of claim 8, wherein the resin is a blend of a resin matrix and a filler, the resin matrix comprises one or more of polyphenylene ether, cyanate ester, epoxy resin, benzoxazine, hydrocarbon resin, bismaleimide and polytetramethylene, and the filler comprises at least one of organic microspheres, silica and titania.

14. The printed circuit board of claim 13, wherein a particle size of the filler is 0.1 μm to 5 μm.

15. A method for manufacturing the printed circuit board of claim 8, comprising:
impregnating a surface fiber felt or a non-woven fabric with resin, and drying the impregnated surface surface fiber felt or impregnated non-woven fabric to obtain a first insulating layer prepreg;
laying the copper foil layer on the first insulating layer prepreg, and then performing a predetermined thermosetting process on the copper foil layer and the first insulating layer prepreg that are laid up to obtain a copper-clad laminate; and
performing exposing, developing, etching and surface treatment processes on the copper-clad laminate according to a designed circuit to obtain the printed circuit board.

16. The method of claim 15, wherein a fiber volume of the first insulating layer accounts for 20%-85% of the total volume of the first insulating layer.

17. The method of claim 16, wherein the fiber is one of a glass fiber, a quartz fiber and an organic fiber.

18. The method of claim 15, wherein the at least one first insulating layer comprises two layers which are spaced from each other, the insulating substrate further comprises a second insulating layer sandwiched between the two first insulating layers, the copper foil layer is attached to a side of the first insulating layer away from the second insulating layer, and the second insulating layer is made of a fiber-reinforced composite material.

19. The method of claim 18, wherein a volume fraction of the fiber volume of the second insulating layer to the total volume of the second insulation layer is equal to a volume fraction of the fiber volume of the first insulating layer to the total volume of the first insulation layer, and the fiber volume of the first insulating layer accounts for 20%-85% of the total volume of the first insulating layer.

20. The method of claim 15, wherein the resin is a blend of a resin matrix and a filler, the resin matrix comprises one or more of polyphenylene ether, cyanate ester, epoxy resin, benzoxazine, hydrocarbon resin, bismaleimide and polytetramethylene, and the filler comprises at least one of organic microspheres, silica and titania.
